(19) United States
(12) Patent Application Publication
(10) Pub. No.: US 2025/0370022 A1
(43) Pub. Date: Dec. 4, 2025

(54) A SYSTEM AND A METHOD FOR ENERGISED CONDUCTOR PHASE IDENTIFICATION BASED ON SYNCHRONOUS MEASUREMENTS USING A NETWORK MODEL

(71) Applicant: GRID INSTRUMENTS D.O.O., Cruce (SI)

(72) Inventor: Urban KUHAR, Cruce (SI)

(21) Appl. No.: 18/993,565

(22) PCT Filed: Jul. 11, 2023
(86) PCT No.: PCT/EP2023/069249

§ 371 Date: Jan. 12, 2025

(30) Foreign Application Priority Data
Jul. 12, 2021 (EP) 22184562.1

(51) Int. Cl. G01R 29/18; H02J 13/00

(52) U.S. Cl. CPC G01R 29/18; H02J 13/00001

(57) ABSTRACT

The method for energised conductor phase identification based on synchronous measurements using network model is performed with a system comprising a field device, a reference device and a server unit connectable to said reference and field devices, wherein the server is provided with a network model comprising information about connectivity, locations of network nodes, busbars, transformer units, field rotation, transformer vector groups and information about other phase shifting devices present in the network. In comparison to known methods, no measurements files are needed, but the identification of conductor phase is performed by matching the field device measurements to the selected reference device measurements, followed by application of the existing knowledge about network model (identification of transformers, field rotation, and connectivity in the network) and calculation of the phase shift from installed reference devices to all or selected busbars in the network model by a software installed and running either on the server, and/or the field device and/or the reference device.

### PRIOR RELATED APPLICATIONS

The present application is a National Entry of PCT Application No. PCT/EP2023/069249, filed on Jul. 11, 2023, which claims priority under the Paris Convention to European Application No. 22184562.1, filed on Jul. 12, 2022. The entire contents of such prior applications are incorporated by reference herein.

### TECHNICAL FIELD

The present invention belongs to the field of (distribution) power network measuring and testing, particularly to the phase identification of a power conductor. The invention relates to a system and a method for energised conductor phase identification based on synchronous measurements using a network model.

### BACKGROUND OF THE INVENTION AND THE TECHNICAL PROBLEM

Power networks are used to deliver electrical energy from generating plants to customers. A wide spread grid is used for stable and safe delivery of electrical energy. In said grid, different voltage levels are used to keep ohmic losses as low as possible. Voltage levels are defined and depend on the country and possibly the area of operation and are changed on the transformer stations. Lowest voltage in the grid, which is in the majority of the world 240 or 120 volts, is then connected to residential and commercial users. Multiple conductor phases, normally three, are employed for the distribution and transmission. A phase attribute of A, B, C or 1, 2, 3 or u, v, w are typically assigned to each of the three conductors to identify them.

Conductor phases are usually assigned arbitrarily on the substation on the transmission or distribution level and later on serve as references, as the primary goal is to properly identify conductor phases within the substation area. But still greater benefits can arise if the whole network of a utility follows a single reference assignment of phases.

Knowledge on the conductor phase is important. There are situations when incorrect knowledge on the conductor phase may cause severe damage on equipment and can even present life-threatening situations to the operating personnel. An example of such a situation would be connecting two electricity sources together. Further, the load in the distribution network needs to be distributed as evenly as possible, as the network losses are thus lower and asset utilisation is greater.

In the networks, the phasing of conductors is often incorrect or even unknown. At the time of the construction of the grid the key points might have been labelled with the phase designation, but through daily operation the labelling is often lost or rendered false. The technical problem is development of a method for allowing identification of the conductor phase in a simple and reliable manner.

### PRIOR ART

Various methods are known for tracking or identifying the phase of electrical conductors in the power grid. Phase identification instruments that rely on the synchrophasor measurements compare instantaneous phase measurements on two different locations collected at the same time. The first device, usually referred to as a reference unit, is located where the conductor phase is identified or assigned. The second device, usually referred to as a field unit, is located where the conductor phase is unknown.

Existing synchrophasor based phase identification instruments differ primarily in the variety of the data they use in the procedure of identifying the conductor phase. In documents U.S. Pat. No. 6,642,700 and US20100194378 a device and method that compare only instantaneous phase measurements were described. If the difference between the two measurements collected simultaneously is close to zero, the unknown conductor phase is the same as the one measured on the reference unit. If the measured difference is 120° or 240°, the unknown conductor phase is one of the other two options, depending on the regulations or utility selection of the phase rotation. For example, if the reference unit is measuring the A (or first) phase, and the field unit is also measuring the A (or first) phase, the difference between the instantaneous phase measurements is approximately 0°. If the field unit is measuring the B (or second) phase the difference between the instantaneous phase measurements is approximately 120° or 240°.

The main problem with usability of such devices is the complicated use of such a system, as the operator of the mobile unit needs to know the upstream network model to correctly account for transformer vector groups and field rotation or for other phase shifting devices. This problem can be mitigated with the use of measurement files stored and provided either by a field client or by a server as described in patent U.S. Pat. No. 9,255,954. The method is such that at the point of measurement the phase attribute is assigned by the user (either A, B, or C) and the measurement file stores the selected phase attribute along with the measured phase offset to one or more installed reference devices. This enables the user to use the stored or provided measurement file and apply the stored phase offsets in subsequent measurements removing the complexity of manually keeping track of phase offsets to the reference devices. The system, as such, behaves as if another reference device is installed at the point of measurement where the measurement file was created.

The drawback of the described method is that at the creation of the measurement file the user selects the phase attribute (either A, B, or C) and potentially two measurement files can be in conflict for the same point of measurement. Another related case would be, where application of two different measurement files that were created at different points would result in different phase determinations. Ultimately, it is the responsibility of the user to ensure coherent creation and application of measurement files. In addition, to have the benefit of measurement files, measurement files need to be created (distributed and maintained) which presents additional step(s) in the process.

US2021285994 discloses a method of phase identification, comprising:
receiving voltage measurements, the voltage measurements including a plurality of customer voltage time series;
obtaining distribution connectivity information;
normalizing the plurality of customer voltage time series by their respective standard deviations;
defining constraints for a clustering process by inspecting the distribution connectivity information;
applying constrained and unconstrained clustering to partition customers into a plurality of clusters; and
identifying a phase of each of the plurality of clusters by solving a minimization problem.

Furthermore, this document also discloses a system comprising:
a computer-readable medium having instructions stored thereon, which, when executed by a processor, cause the system to:
receive voltage measurements, the voltage measurements including a plurality of customer voltage time series;
obtain distribution connectivity information;
normalize the plurality of customer voltage time series by their respective standard deviations;
define constraints for a clustering process by inspecting the distribution connectivity information;
apply constrained clustering to partition customers into a plurality of clusters; and
identify a phase of each of the plurality of clusters by solving a minimization problem.

This document uses a methodology of phase identification from collected data taken in longer time periods, which is in contrast with the present invention that allows phase identification in real time for a selected point in an analysed network.

### Description of the Solution to the Technical Problem

The present invention aims to address the disadvantages of currently known devices and methods for conductor phase identification. The main contribution is that phase identification is enabled in real time. The technical problem is solved as defined in independent claims, wherein preferred embodiments of the invention are defined in dependent claims.

The usual system needed for identification of the conductor phase comprises at least one reference device installed in the inspected network and at least one field device connectable to the at least one reference device in order to compare the measurements. The reference device comprises a signal conditioning, data acquisition and processing modules, while the field device comprises signal conditioning, data acquisition, processing modules, and a user interface.

The essence of the invention is that the system further comprises a server unit connectable to said reference and field devices, wherein the server is provided with a network model comprising information about the network. This information includes at least data about connectivity, locations of network nodes, busbars, transformer units, field rotation at transformers, transformer vector groups, and other phase shifting devices present in the network. Thus, said server comprises a database of timestamped phasor measurements from all available reference devices in the same synchronous grid, a database of relevant part of the power network model where all busbars and lines are geotagged. Besides connectivity the network model contains information about transformer vector groups and field rotation, as well as information about any other phase shifting devices present in the network as this is essential information for correctly determining signal phase offset. These offsets can be specified by the manufacturer of the device or experimentally determined (measured on the field). In comparison to known methods, no measurements files are needed (stored measurements of phase offsets applied in subsequent measurements), but the identification of conductor phase is performed by matching the field device measurements to the selected reference device measurements, followed by application of the existing knowledge about network model (identification of transformers, field rotation, and connectivity in the network) and calculation of the phase shift from installed reference devices to all or selected busbars in the network model. Phase identification is enabled by a software for said identification and calculation installed and running either on the server, and/or the field device and/or the reference device, wherein the following steps are applied:
a) Connection of the field device to the server and receipt of a field measurement request by the server,
b) Checking of available reference devices and suggestion of the most suitable reference device for matching of measurements with the field device,
c) Obtaining the last available, accurate network model from either a file, database or other repository, usually Supervisory Control and Data Acquisition (SCADA) system, Advanced Distribution Management System (ADMS), or Geographic Information System (GIS),
d) Checking for calculated phase offset for the selected busbar in the network model,
   If there are no phase offsets stored, phase offsets are calculated for all buses in the network model and stored in the database, or
   If there are phase offsets stored, the database of selected reference devices is queried for the received field measurement request timestamp, the offset database is queried for the selected busbar and the found data are sent as results to the field device.

The network models and/or calculation modules are stored on the server unit, however, they could also be stored on either field or reference devices or any other third-party devices. This is less practical, hence the server configuration as described above is preferred.

The implementation of the phase offset calculation module can be done in multiple ways. One possible embodiment is to assume no-load conditions in the network and that for each bus with a reference device is assigned zero phase offset, wherein phase offsets for other busses in the network are calculated considering whether a connecting branch is a transformer or other phase shifting device and in case, it is, considering field rotation to determine the phase offset. The following recursive function is one example of such implementation:

```
calculate_offsets(current_bus, current_offset)
  connected_busses = get_connected_busses(current_bus)
  foreach bus in connected_busses
    phase offset not yet assigned to the bus?
      offset = current_offset
      is the connecting branch between current_bus and bus a
transformer?
        is field rotation on the transformer positive?
          offset = offset + transformer vector group
        else
          offset = offset − transformer vector group
      else is the connecting branch between current_bus and bus
other phase shifting device?
        offset = offset + additional phase shift
      save_bus_offset(bus, offset)
      calculate_offsets(bus, offset)
```

In other words, the method comprises the following:
Offset at any selected reference device is assumed to be 0°,
Checking of connected busses and connecting branch types, wherein for each identified connected bus, the system checks if there is a transformer or other phase shifting device in between; wherein, if yes, phase offset is added to the current phase offset with proper consideration of relevant parameters such as field rotation; and wherein if there is no phase shifting device between the busses, offset remains to be the previously assumed 0 for the connected bus,
Repeating the above steps for each following bus connected to the previous bus to cover all connections in the relevant tested network or its part.

For larger networks, where line inductances are larger and loadings are significant, loads may need to be considered to correctly account for phase shifts that are the result of line currents. One possible way of implementation in such a network is that the three-phase or single-phase power-flow (Computer Analysis of Power Systems, Jos Arrillaga, C. P. Arnold, Wiley 1991) is calculated which results can be used to determine correct phase offsets between reference devices and other buses in the network.

The accurate operational network model enables the user to select the nearest available upstream busbar and the client or server software will recalculate the phase shift offset from one or more reference devices to the selected busbar. The phase shift offset can also be calculated using power-flow (Computer Analysis of Power Systems, Jos Arrillaga, C. P. Arnold, Wiley 1991) or similar technique under either nominal or any other load conditions.

Furthermore, the system preferably comprises a mobile application installed on a mobile device such as a smartphone, tablet or similar, wherein the mobile application is connectable to the field device and displays data about network model, calculated phases and related data. Said mobile application allows the entry of a correction of a specific parameter of the network model, such as transformer field rotation of vector group, to be applied on the server stored network model.

The present invention allows quick identification of conductor phases without any interventions in the power network.

The invention will be described in further detail based on exemplary embodiments and figures, which show:

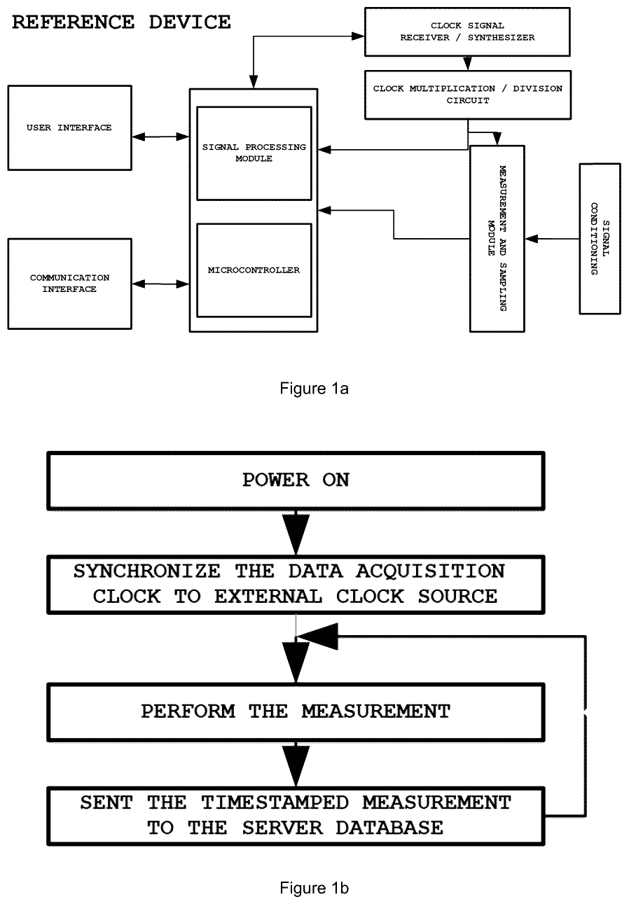

FIG. 1a Block diagram of the reference device

FIG. 1b Flow-chart of the reference device operation

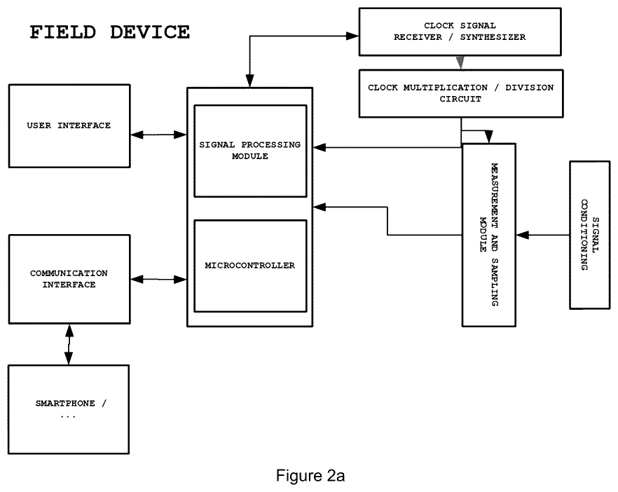

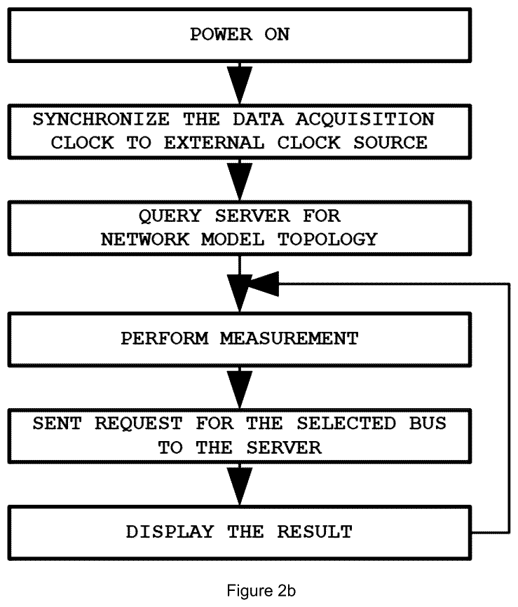

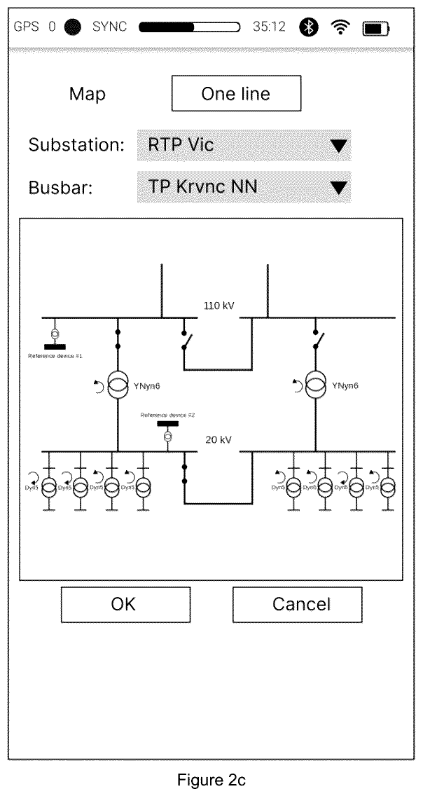

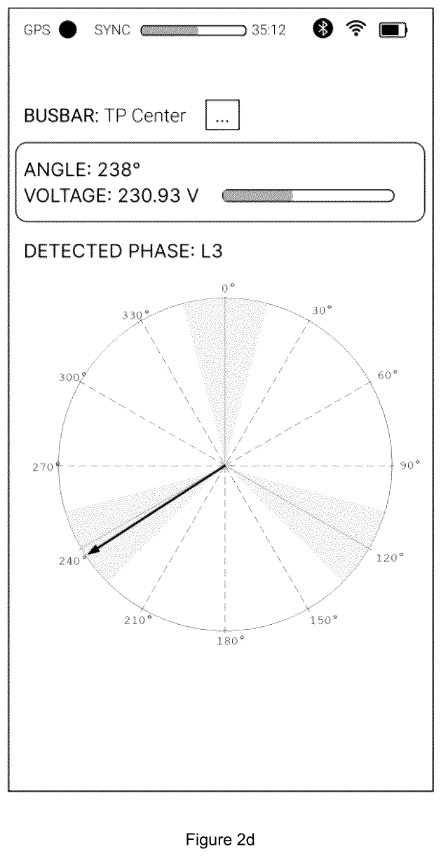

FIG. 2a Block diagram of the field device

FIG. 2b Flow-chart of the field device operation

FIG. 2c Exemplary view of smartphone application for bus selection in a loaded network model

FIG. 2d Exemplary view of smartphone application for phase identification

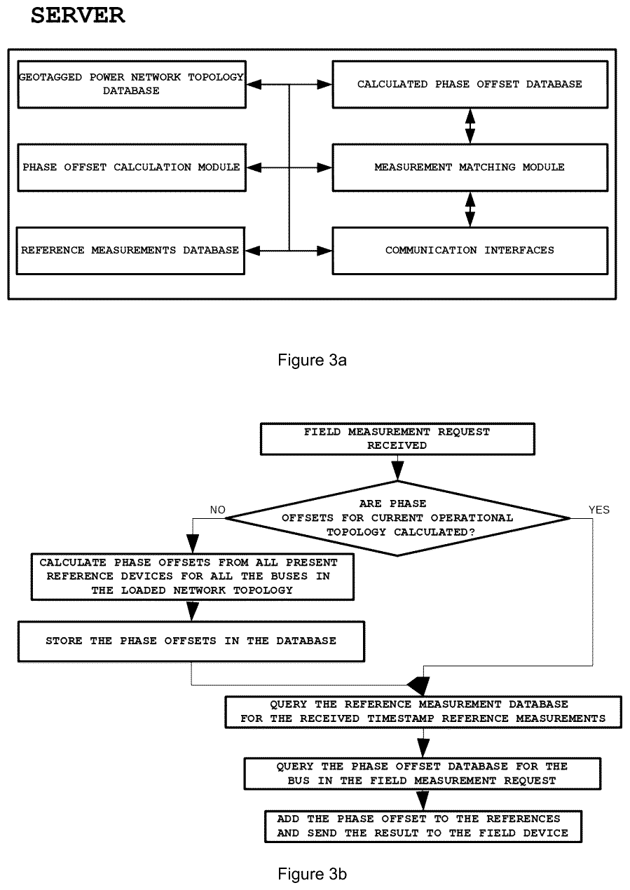

FIG. 3a Databases on the server

FIG. 3b Flow-chart of server operation

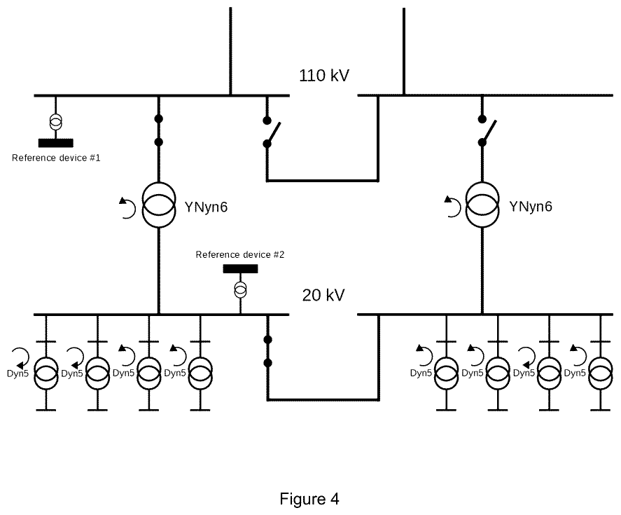

FIG. 4 An example of a power network model as stored and shown on web-server or smartphone application

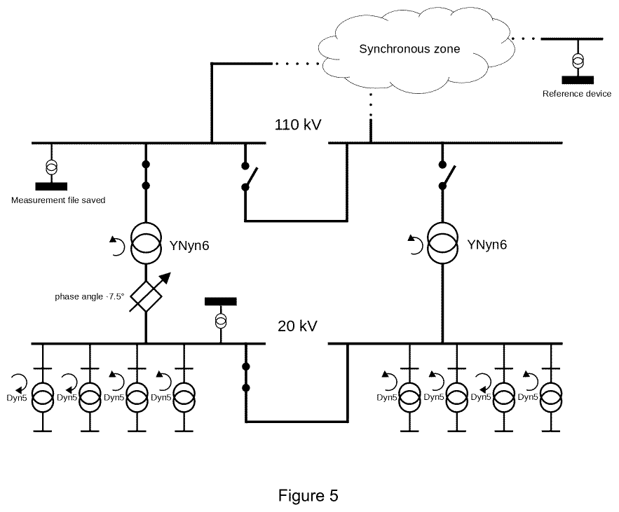

FIG. 5 An example of a power network model as stored and shown on web-server or smartphone application with measurement file for a reference device in a synchronous zone

The system that implements the method according to the invention comprises at least three functional elements, namely at least one reference device, at least one field device and a server unit. Optionally, the field device is connectable to a mobile device with a mobile application displaying relevant data connected to the method of identification of conductor phase.

FIG. 1a shows an embodiment of the reference device, which comprises signal conditioning, a module for measurement and sampling, a signal processing module, a microcontroller as well as clock signal receiver and clock multiplication/division circuit, which are interacting with the signal processing module and the module for measurement and sampling. The microcontroller communicates phasor estimations through a communication interface to the server. The user interface is used to present basic status information about the device, for example if the device is successfully connected to the server and if it is synchronised to the master clock.

The reference device operates in the following manner (FIG. 1b): after signal conditioning and acquisition, the digitised signal of voltage or current is fed into phasor estimation algorithm, which produces the stream of time stamped phasor estimations (Synchronized Phasor Measurements and Their Applications, A. G. Phadke, J. S. Thorp, Springer 2008). The stream of phasor estimations is sent over the communication channel to the server.

If there are multiple reference devices installed in the network, care must be taken in connecting each of the devices following the first one in order that the new connected device follows the phase designation as it is used in the first device, considering the correct network model and phase offsets due to the model.

The field device is shown in FIG. 2a and comprises signal conditioning, data acquisition (measurement and sampling module, clock signal receiver/synthesiser and clock multiplication/division circuit), a signal processing module in communication with a user interface, a microcontroller in communication with a communication interface optionally communicating with a smartphone or similar device.

The flow-chart of the field device operation is shown in FIG. 2b. After power-on the field device synchronises to the external clock source. Once synchronisation is achieved, the device starts performing measurements. The implementation of the device can be such that the field device connects to the smartphone via Bluetooth or other wireless or wired technology and streams the measurements to the mobile phone which serves as a user interface. The application on either the field device or smartphone (if smartphone is paired with the field device) then requests the network model for it to be presented to the user, wherein the network model is accessed via the server. Server responds with the network model and the user can select a bus in the network against which he wants to reference the measurements (FIG. 2c). The selected bus is normally the closest one upstream in the network. Measurement acquisition is performed by conditioning of the voltage or current signal, its digitalization and processing which produces the phasor estimation (much like on the reference device). The phasor estimation result is then communicated to the microprocessor in the device or to an outside device such as a smartphone, where it is sent to the server with accompanying information about the selected network bus as a reference against which the measurement needs to be matched. Upon receiving the request, the server will query the database of reference measurements and return the matching reference measurement and then query the phase offset database for the selected network bus to correctly apply the offset and return the result to the user (see also the server operation flowchart). The result can be then displayed in the form of a phasor diagram (FIG. 2d).

The server unit as shown in FIG. 3a comprises:
Accurate operational network model of the area where field measurements will be performed, which comprises:
   information about transformer vector groups and field rotation and/or other phase shifting devices in the network, as this is essential information for correctly determining signal phase offset,
   a database of relevant part of the power network model where all busbars and lines are geotagged, and
   a database with previously determined phase offsets for all available reference devices, matched to the buses in the said network model,
a database of timestamped phasor measurements from all available reference devices,
a communication module for communication with field and reference devices, and
a measurement matching module for querying the database of reference measurements, matching the received field measurement request with the selected reference measurement and applying the calculated phase offset.

The preferred operation mode of the server once set up and provided with the necessary network model comprises the following steps (FIG. 3b):
a) Connection of the field device and receipt of a field measurement request,
b) Checking of available reference devices and suggestion of the most suitable reference device for establishing connection with the field device,
c) Checking for calculated phase offsets for the selected network model,
   If there are no offsets calculated, phase offsets are calculated for all buses in the network model and stored in the database, then
   If there are offsets calculated, a database of reference measurements is queried for timestamp received in the field measurement request, the offset database is then queried and the returned data is sent as results to the field device.

The network model stored on the server comprises at least:
information about the network connectivity,
information about transformer vector groups and other phase shifting devices and
information about field rotation on each of the transformers present in the network.

At least a part of the network model for the area where field measurements will be performed has to be available, which comprises at least one installed reference device or a measurement file that stores the phase offset to the reference device outside the said network model, but within the same synchronous zone, to a particular busbar in the stored network model (U.S. Pat. No. 9,255,954B2), down to the last transformer before the measurement point.

FIGS. 4 and 5 show examples of power network models consisting of said information about the network connectivity, transformer vector groups and field rotation on each of the transformers present in the network or information about other phase shifting devices present on the branches in the network.

The following recursive function represents the preferred embodiment of the invention:

```
calculate_offsets(current_bus, current_offset)
  connected_busses = get_connected_busses(current_bus)
  foreach bus in connected_busses
    phase offset not yet assigned to the bus?
      offset = current_offset
      is the connecting branch between current_bus and bus a
transformer?
        is field rotation on the transformer positive?
          offset = offset + transformer vector group
        else
          offset = offset − transformer vector group
      else is the connecting branch between current_bus and bus
other phase shifting device?
        offset = offset + additional phase shift
      save_bus_offset(bus, offset)
      calculate_offsets(bus, offset)
```

The implementation of the phase offset calculation according to a possible embodiment is thus the following:
no-load condition in the network is assumed and
for each bus with a reference device is assigned zero offset,
   wherein offsets for other busses in the network are calculated considering whether a connecting branch is a transformer or other phase shifting device and in case, it is, considering field rotation to determine the phase offset.

The phase shift in case of transformers is determined based on information about the transformer connection, e.g., vector group 6 shifts the phases for 6*30°=180°.

1. A system for performing a method for energized conductor phase identification based on synchronous measurements using a network model, wherein said system comprises:
at least one reference device installed in an inspected network, or at least one reference device installed outside the inspected network, but within the same synchronous zone, connected through a measurement file that stores the phase offset from the busbar in the model to the reference device outside the inspected network,
at least one field device connected to the at least one reference device in order to obtain data about the inspected network,
characterized in that the system further comprises a server unit connected to said reference and field devices, wherein the server is provided with a network model comprising information about the inspected network, said information including at least data about connectivity, locations of network nodes, busbars, transformer units, field rotation at transformers, transformer vector groups, and other phase shifting devices present in the inspected network.

2. The system according to claim 1, wherein the reference device comprises a signal conditioning module, a data acquisition model and a processing module, while the field device comprises a signal conditioning module, a data acquisition module, a processing module, and a user interface.

3. The system according to claim 1, wherein the identification of conductor phase is performed by matching the field device measurements to the selected reference device measurements, followed by application of the existing knowledge about network model, including identification of transformers, field rotation, and connectivity in the network, and calculation of the phase offset from installed reference devices to all or selected busbars in the network model.

4. The system according to claim 1, wherein phase identification is enabled by a software for said identification and calculation installed and running either on the server, and/or the field device and/or the reference device, wherein the following steps are applied:
a) connection of the field device to the server and receipt of a field measurement request by the server,
b) checking of available reference devices and suggestion of the most suitable reference device for matching of measurements with the field device,
c) obtaining the last available, accurate operational network model from either a file, database or other repository, preferably Supervisory Control and Data Acquisition (SCADA) system, Advanced Distribution Management System (ADMS), or Geographic Information System (GIS),
d) checking for calculated phase offset for the selected busbar in the network model,
if there are no phase offsets stored, phase offsets are calculated for all buses in the network model and stored in the database,
if there are phase offsets stored, the database of selected reference device is queried for the received field measurement request timestamp, the offset database is queried for the selected busbar and the found data are sent as results to the field device.

5. The system according to claim 1, wherein the system further comprises a mobile application that can be installed on a mobile device such as a smartphone, tablet or similar, wherein the mobile application is connectable to the field device and displays data about network model, calculated phase offsets, phase identification result, and related data.

6. The system according to claim 1, wherein the mobile application allows the entry of a correction of a specific parameter of the network model, such as transformer field rotation or vector group number, to be applied on the server stored network model.

7. A method for energized conductor phase identification based on synchronous measurements using a network model performed by the system according to any of the preceding claims, said method comprising the following steps:
a) connection of the field device to the server and receipt of a field measurement request by the server,
b) checking of available reference devices and suggestion of the most suitable reference device for matching of measurements with the field device,
c) obtaining the last available, accurate network model from either a file, database or other repository,
d) checking for calculated phase offset for the selected busbar in the network model,
if there are no phase offsets stored, phase offsets are calculated for all buses in the network model and stored in the database,
if there are phase offsets stored, the database of selected reference devices is queried for the received field measurement request timestamp, the offset database is queried for the selected busbar and the found data are sent as results to the field device.

8. The method according to claim 7, wherein the step c) the network model is obtained from Supervisory Control and Data Acquisition (SCADA) system, Advanced Distribution Management System (ADMS), or Geographic Information System (GIS).

9. The method according to claim 7, wherein no-load conditions in the network are assumed and that for each bus with a reference device is assigned zero phase offset, wherein phase offsets for other busses in the network are calculated considering whether a connecting branch is a transformer or other phase shifting device and in case, it is, considering field rotation to determine the phase offset due to the said transformer or device.

10. The method according to claim 7, wherein phase offset calculation module is implemented as a recursive function:
```
calculate_offsets [current_bus, current_offset]
  connected_busses = get_connected_busses [current_bus]
  foreach bus in connected_busses
    phase offset not yet assigned to the bus?
      offset = current_offset
      is the connecting branch between current_bus and bus a
      transformer?
        is field rotation on the transformer positive?
          offset = offset + transformer vector group
        else
          offset = offset − transformer vector group
      else is the connecting branch between current_bus and bus other
      phase shifting device?
        offset = offset + additional phase shift
      save_bus_offset [bus, offset]
      calculate_offsets [bus, offset].
```

11. The method according to claim 1, wherein for larger networks three-phase or single-phase power-flow is calculated and obtained results are used to determine correct phase offsets between reference devices and other buses in the network.
